(19) United States
(12) Patent Application Publication
(10) Pub. No.: US 2007/0056620 A1
(43) Pub. Date: Mar. 15, 2007

(54) Power connection for a thin film thermoelectric cooler

(76) Inventors: Christopher Joseph Bahr, Maricopa, AZ (US); John Stephen Guzek JR., Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/225,305

(22) Filed: Sep. 12, 2005

(51) Int. Cl. H01L 35/34; H01L 35/28

(52) U.S. Cl. 136/201; 136/203

(57) ABSTRACT

A method and apparatus for providing power to a thin film thermoelectric cooling (TFTEC) device disposed between a heat generating device, such as a semiconductor device, and a cooling device, such as an integrated heat spreader. An electrically conductive pathway may be electrically coupled at one end to the TFTEC and also to an electrically conductive feature on the surface of a substrate at the other end. The electrically conductive pathway itself may be routed and retained in close proximity to the cooling device between the TFTEC and the substrate.

### FIELD OF THE INVENTION

This invention relates generally to the field of thermal management of devices. In particular, the present invention relates to a method and apparatus for providing power to a thin film thermoelectric device.

### BACKGROUND OF THE INVENTION

Until recently, semiconductor devices have generated only such amounts of heat while operating to allow them to be sufficiently cooled based on passive thermal conduction and air cooling. However, several recent factors, including more densely integrated circuit designs, higher operating speeds and higher power demands have led to successive generations of semiconductor devices requiring more active, effective cooling solutions. Included among the solutions proposed and implemented are liquid-vapor phase change solutions, refrigeration, thermoelectric coolers (TECs), and others.

Despite the numerous cooling solutions in use and proposed for use, few are able to efficiently and effectively address the presence of ‘hot spots’ in semiconductor devices, that is, areas of a semiconductor device with significantly higher thermal output than the rest of the device. Most current active cooling devices are designed to remove heat relatively uniformly across their effective surface area, with variations driven more by the physics of the materials involved and rates of thermal conduction across a thermal differential than by the design and structure of the cooling device. Most current and proposed cooling solutions must be designed large enough and effective enough, across their entire effective dimensions (e.g., length and width), to meet the needs of the hot spots while also cooling other portions of the semiconductor device. These objectives are further complicated as the size of semiconductor devices and packages shrink as a result of technology developments, and lead to larger, inefficient cooling devices that increase the overall size of the device in which they are used. Consequently, these cooling solutions either may not be used in smaller and/or more mobile devices, or they will drive an increase in the size of those devices, making them less desirable in a consumer market increasingly demanding small size, convenience, and portability.

TECs contain discrete units composed of dissimilar materials, which, when subjected to a current, generate a thermal differential whereby one type of junction within the device heats up and another type of junction cools down. TECs may be implemented as modules large enough to be assembled to semiconductor devices by a ‘pick and place’ manual or automated assembly process. Further, their size typically requires that they be placed adjacent to an intermediate thermally conductive cooling device such as an integrated heat spreader (IHS). The IHS and the various thermal interface materials typically used both between an IHS and a semiconductor device, and between an IHS and a TEC, reduce the efficiency of the TEC for cooling the semiconductor device by increasing resistance to thermal flow. To be most effective, TECs should be placed as close as possible to the semiconductor device where the heat is generated, with as few intervening materials as possible. This may mean placing a thin film thermoelectric cooling device (TFTEC) between the semiconductor device and an IHS or another larger scale passive or active cooling device, or possibly even on the semiconductor die itself.

While this approach may reduce the thermal resistance by removing some interceding materials, it may create a challenge for supplying power to a TFTEC located between a cooling device, such as an IHS, and a heat generating device, such as a semiconductor device. An IHS is typically assembled to a substrate so that a semiconductor device is positioned in a cavity below the IHS. The lip of the IHS, which substantially defines the cavity, may closely approach or even be adhered in contact with the surface of a substrate or a semiconductor package to which the semiconductor device is assembled. Therefore, a power cable cannot later be readily connected to a TFTEC located beneath the IHS. Currently, no solution is known for providing power to a TFTEC located beneath an IHS.

### BRIEF DESCRIPTION OF THE DRAWINGS

FIG. 1 depicts a cross-sectional view of an assembly according to an embodiment of the invention.

FIGS. 2a-2e depict transverse cross-sectional views of means for routing an electrically conductive pathway and retaining an electrically conductive pathway in proximity to a cooling device according to embodiments of the invention.

FIG. 3 depicts an oblique view of a portion of the cavity of an integrated heat spreader including an embodiment of the invention.

FIG. 4 depicts a block diagram of a method for providing a power connection according to embodiments of the invention.

### DETAILED DESCRIPTION OF THE INVENTION

Described herein are embodiments of a method and apparatus for supplying power to a TFTEC, including exemplary embodiments presented to provide a clear understanding of the nature and scope of the invention. By the described embodiments of the invention, use of a TFTEC beneath an integrated heat spreader (IHS) or other cooling device may be enabled to more effectively and efficiently cool a heat generating device.

For simplicity, portions of this description may describe embodiments of a completed assembly so that positional relationships may be more clearly understood. For example, a portion of a cooling device proximate to a substrate may be described. It should be understood that these exemplary descriptions do not limit the scope of described embodiments of the invention to a cooling device provided proximate to a substrate, but also are intended to describe, for example, a cooling device which is not proximate to a substrate, the references to a substrate being provided to clarify positional descriptions of portions of the cooling device as they would relate to a substrate when used in an application including a substrate.

Throughout this description, reference is made to a thin film thermoelectric cooling device (TFTEC), and also to simply a cooling device, and should be understood to apply to different cooling devices.

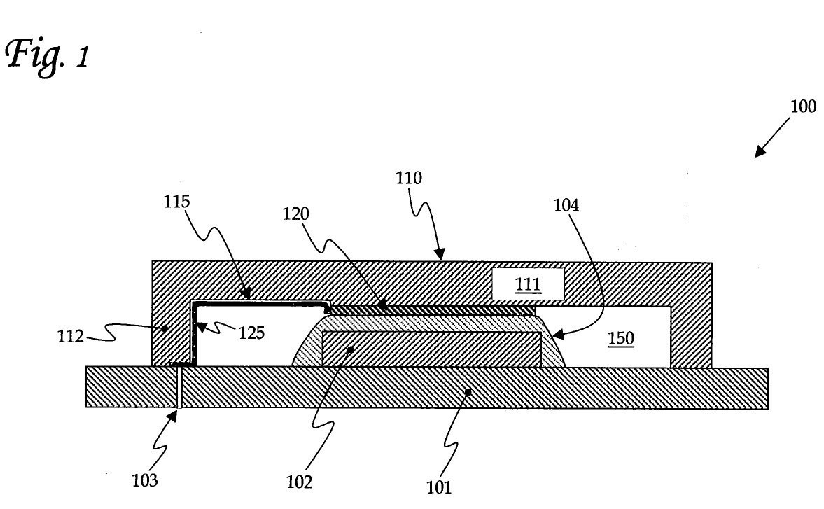

FIG. 1 depicts an exemplary embodiment 100 of the invention. A heat generating device 102 is disposed adjacent to a substrate 101. A cooling device 110 is then disposed adjacent to the substrate 101 and the heat generating device 102. Disposed adjacent to the cooling device 110 is a thin film thermoelectric cooling (TFTEC) device 120 that may be substantially aligned with the heat generating device 102. In embodiments, a TFTEC 120 may be disposed directly adjacent a heat generating device 102, substantially aligned to a hot spot of the heat generating device 102, wherein the surface of the heat generating device 102 adjacent to the TFTEC 120 may also function as a substrate 101.

A thermal interface material (TIM) 104 may be disposed adjacent to the heat generating device 102 and the TFTEC 120, thermally coupling, and in some embodiments physically coupling, the heat generating device 102 and the TFTEC 120. Electrically coupled at one end to the TFTEC 120 and at the other end to an electrically conductive feature 103 of the substrate 101 may be an electrically conductive pathway 125, retained in close proximity to the cooling device 110. As shown in FIG. 1, a channel 115 may be formed in the cooling device 110 providing both a means for routing the electrically conductive pathway 125 from the TFTEC 120 to the electrically conductive feature 103, and in embodiments, also a means for retaining the electrically conductive pathway 125 in close proximity to at least a portion of the cooling device 110.

Between the cooling device 110 and the substrate 101 may be a cavity 150, the perimeter of which may be substantially defined by a lip 112, rim, or other similar structure formed as part of the cooling device 110. The outer perimeter of the lip 112 may define the outer perimeter of the cooling device 110, as depicted in the exemplary embodiment 100, while in other embodiments there may not be a lip 112, or the outer perimeter of the cooling device 110 may extend beyond the outer perimeter of a lip 112. The cooling device 110 may be disposed adjacent to the substrate 101 so that the electrically conductive feature 103 may be located entirely within the outer perimeter of the cooling device 110, or in other embodiments, the electrically conductive feature 103 maybe be located partially within and partially outside, or entirely outside the outer perimeter of the cooling device 110.

A substrate 101 may include an integrated circuit substrate. Embodiments of an integrated circuit substrate may include, but not exclusively so, a printed circuit substrate. Examples of a printed circuit substrate according to embodiments of the invention may include printed circuit boards, add-in cards (e.g. memory cards, input/output (I/O) cards, audio/graphics cards, network, telephony, wireless), flexible circuit substrates, patterned wafers (e.g. silicon, germanium) and semiconductor device packaging materials which include electrically conductive pathways.

In embodiments, as mentioned, a portion of a heat generating device 102 may also function as a substrate when a cooling device 110 is disposed adjacent the heat generating device. Conversely, it may be understood that embodiments of an integrated circuit substrate as discussed above may also be a heat generating device 102 according to embodiments of the invention. A heat generating device 102 may be any device with a thermal output, whether, in embodiments, the heat output results from a conversion of chemical, electrical, light or some other form of energy within the device to heat energy, or whether, in other embodiments, the heat energy entered the device conductively or radiatively from some other source. Examples of heat generating devices according to exemplary embodiments may include integrated circuit devices, semiconductor devices, integrated circuit substrates, power regulation devices, and other signal processing devices, including but not limited to microprocessors, chipsets, multimedia generating and processing devices (e.g. graphics, audio), input/output (I/O) devices, memory devices, network devices, telephony devices, microcontrollers, wireless communication devices, printed circuit boards (PCBs), packaged integrated circuit devices, power regulating devices, optoelectronic devices, multi-chip packaged devices (e.g. flip chip), multi-chip modules (MCM) and others. In embodiments where heat energy may enter a first stage cooling device conductively or radiatively from a heat generating device, the first stage cooling device may also be considered a heat generating device relative to a TFTEC provided to remove heat energy from the first stage cooling device.

A cooling device 110 may be any device designed or implemented for the purpose of aiding in the transfer of thermal energy away from a heat generating device 102 or from another cooling device such as a thermoelectric cooling device 120. In the latter implementation, a cooling device may also be referred to as a ‘second cooling device’, or a ‘second stage cooling device’. A cooling device 110, according to embodiments, may be a passive cooling device, for example, an integrated heat spreader (IHS) or a heat sink, or it may be an active cooling device, for example, a refrigeration device, a multiphase cooling device (liquid-vapor, including heat pipes), a module level TEC, a liquid cooling device, a fan cooling device, or others as are known in the art. For simplicity, any active and passive cooling devices may be referred to herein as ‘cooling devices’. While a passive cooling device, such as an IHS 110 in an exemplary embodiment, as shown in FIG. 1, may have a cavity 150 formed by a flat main portion 111 with a rim 112 describing a perimeter on one surface of the flat main portion 111, not all cooling devices will have a cavity 150 similar to an IHS. It may also be understood that in embodiments of a cooling device 110 with a rim 112, the rim may not form a complete perimeter of a cooling device, but may have areas where the rim is reduced in size or completely absent. In other embodiments, a cooling device 110 may or may not have a rim describing a complete or partial perimeter, such as when a rim is absent, but may have other structures extending away from a main body portion of the cooling device 110, wherein a portion of the structures may extend toward and be disposed proximate to a surface of a substrate 101 when the cooling device 110 is disposed adjacent to a heat generating device 102.

A TFTEC 120 substantially aligned with a heat generating device 102 may be disposed so that the TFTEC is aligned entirely within the borders of the heat generating device (wherein the TFTEC may have a smaller footprint than the heat generating device), or in another embodiment the TFTEC may overlap a border of the heat generating device on some or all sides (wherein the footprint of the TFTEC may be larger or different in shape than that of the heat generating device). A TFTEC 120 may also be the same size as a heat generating device 102, but in any case, substantially aligning a TFTEC does not necessarily mean that the borders of the TFTEC will be directly aligned with those of a heat generating devices. Rather, any part of a TFTEC 120 may be aligned with any part of a heat generating device 102 according to an intent of a user, manufacturer or designer of a TFTEC. In an exemplary embodiment, a portion (‘hot spot’) of a heat generating device 102 may exhibit a significantly higher thermal output than other portions of the device, and a TFTEC 120 may be aligned at least in part with this ‘hot spot’.

In some embodiments, a TFTEC 120 may be disposed immediately adjacent a heat generating device 102 with a surface or feature of the TFTEC in physical contact with the heat generating device. In other embodiments, a thermal interface material 104 (TIM) such as a thermal grease, thermal gasket, cold-formed TIM or solder TIM may be disposed between a heat generating device 102 and a TFTEC 120, wherein the TFTEC is disposed adjacent the heat generating device with a TIM interceding. Therefore, it should be understood that in embodiments of a TFTEC 120 disposed adjacent a heat generating device 102, adjacency may indicate physical contact, or it may simply indicate proximity. In any arrangement, according to an embodiment, wherein heat may flow from a heat generating device 102 to a TFTEC 120 thermally coupled to the heat generating device, it may be said that the TFTEC is disposed adjacent to the heat generating device. Likewise, regarding separate embodiments of a cooling device 110 disposed adjacent to a substrate 101 or adjacent to a heat generating device 102, or a heat generating device disposed adjacent to a substrate, adjacency may include an attachment of one to another, physical contact of one with another, or even simply proximity of one to another, although it should be understood that proximity is an element of adjacency. Therefore, adjacency is not destroyed merely by the presence of one or more materials interposed between two devices, such as two cooling devices 110, or a substrate 101 and a device such as a heat generating device 102, as described in embodiments herein.

An electrically conductive pathway 125 electrically coupled to a TFTEC 120 may, in exemplary embodiments, be a power supply pathway or a ground pathway electrically provided for coupling the TFTEC to an electrical circuit. An electrically conductive pathway 125, according to embodiments, may take any of a number of forms. In embodiments, an electrically conductive pathway 125 may include an electrically conductive cable or assembly (e.g. cord, flex cable, ribbon cable) comprising a plurality of wires encased in a common electrically nonconductive casing, or one or more individually insulated wires. In other embodiments, an electrically conductive pathway 125 may include at least one trace formed onto or into the surface of a cooling device 110. In still another embodiment, an electrically conductive pathway may be a trace formed onto a flexible substrate. Other embodiments may include other means capable of carrying an electrical signal, impulse, or charge.

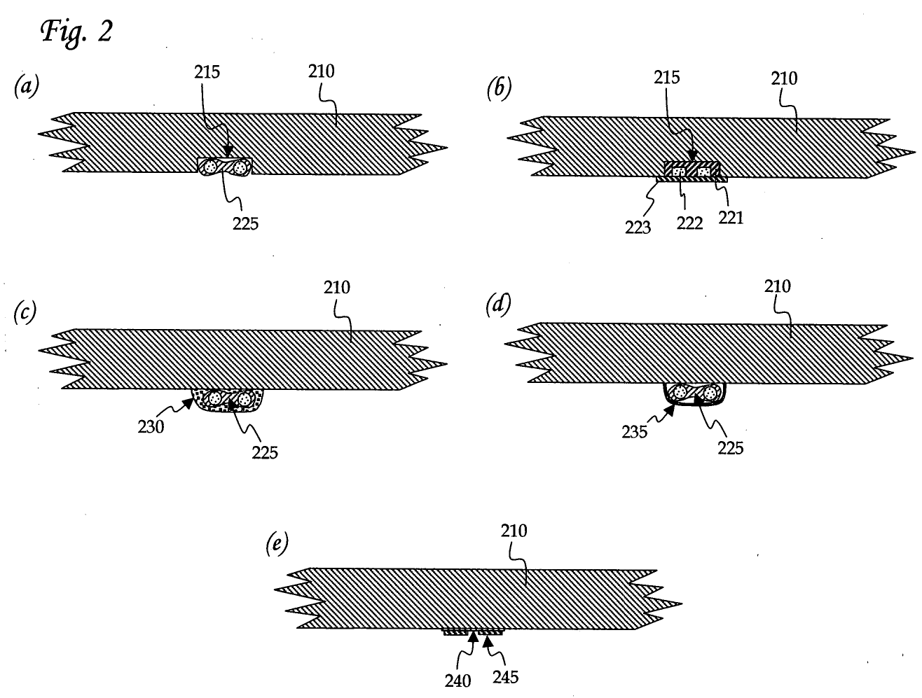

Electrical traces formed onto the surface of a cooling device 110 may be a conductive material, for example a metal, formed by any of numerous methods, such as by sputtering, vapor deposition (e.g. CVD), evaporative deposition, lamination, lithography, electroplating, or other methods. An electrically conductive pathway 125 may also be formed of an electrically conductive polymer, a metallic paste (e.g., solder paste), or a reflowed metal. In an embodiment depicted in FIG. 2b, an electrically insulative (dielectric) material 221 may be disposed in a channel 215 or plurality of channels formed into the surface of a cooling device 210. At least one channel may then be formed into the dielectric material, and an electrically conductive material 222 may be disposed into the channel to form an electrically conductive pathway (e.g., a trace).

Referring to FIG. 2e, in embodiments wherein the surface of a cooling device 210 may be electrically conductive, and an electrically conductive pathway 245 is to be formed on the surface of the cooling device 210, an electrically non-conductive material 240 may be first formed upon the surface of the cooling device, then an electrically conductive pathway (e.g., traces 245) may be formed upon the electrically non-conductive material 240.

In embodiments, an electrically non-conductive material 223 may be disposed substantially covering an electrically conductive pathway (e.g., trace) 222, 245 to prevent an electrically conductive pathway from short circuiting with the electrically conductive surface of a cooling device 110, with an electrically conductive TIM 104, or other electrically conductive materials that may be present. An end of an electrically conductive pathway (e.g., a trace) 222, 245 may be left uncovered to allow electrical coupling with a TFTEC 120, and another end of the pathway may be left uncovered for electrically coupling to an electrically conductive feature 103.

Embodiments of an electrically non-conductive material 240 formed on the surface of a cooling device 110 may include an oxide or nitride material. In other embodiments, an electrically non-conductive polymer may be used, for example, a polyamide material. In still other embodiments, a ceramic material or a spin-on glass (SOG) material may be used. Other embodiments may include other non-conductive materials 240 that may be formed on the surface of a cooling device 210, and upon or into which may be formed an electrically conductive pathway 245.

An electrically conductive feature 103 may be at the surface plane of the substrate, or if not at the surface plane, may be near the surface plane and be exposed for physically and electrically coupling with an electrically conductive pathway 125 provided from the TFTEC 120. An electrically conductive feature 103 according to embodiments of the invention may include a conductive pad, a via 103 (including through vias, blind vias, microvias, and others), a via-in-pad structure, an exposed trace, an exposed power plane, an exposed ground plane, or a terminal of a component. A partial but not exclusive list of components that may be used may include power regulation components, such as capacitors, resistors, inductors, etc., integrated circuit components, I/O components, or others as may be provided, for example, on the surface of a substrate 101. In embodiments, it may also be possible for an electrically conductive feature 103 to include a combination of two or more of those listed here. For example, an electrically conductive pathway 125 may be physically and electrically coupled to a conductive pad on a substrate 101 while it may also be physically and electrically coupled to the terminal of a component.

An electrically conductive pathway 222, 245 may be retained in close proximity to a cooling device 210 by being formed into or onto the cooling device, as in embodiments depicted in FIGS. 2b and 2e, where the electrically conductive pathway may be a trace. An electrically conductive pathway 225 may also be adhered to a cooling device by a thermally stable adhesive material 230, as in FIG. 2c, which maintains its ability to retain an electrically conductive pathway in close proximity to a cooling device 210 when exposed to elevated temperatures, such as those encountered in reasonable usage and storage environments, in manufacturing, and at temperatures generated by the heat generating device 102. An electrically conductive pathway 225 may be retained, in embodiments represented in FIG. 2d, by fasteners or retention structures 235 provided at the surface of the cooling device, such as clips, pins, clamps, bendable retaining arms, or others suitable for retaining an electrically conductive pathway under conditions of elevated temperatures. In an exemplary embodiment depicted in FIG. 2a, a channel 215 may be formed in a cooling device 210, and an electrically conductive pathway 225 may be inserted into the channel 215 so that the electrically conductive pathway 225 is retained by the friction of the pathway 225 against the surfaces of the channel 215, (e.g. compression fit).

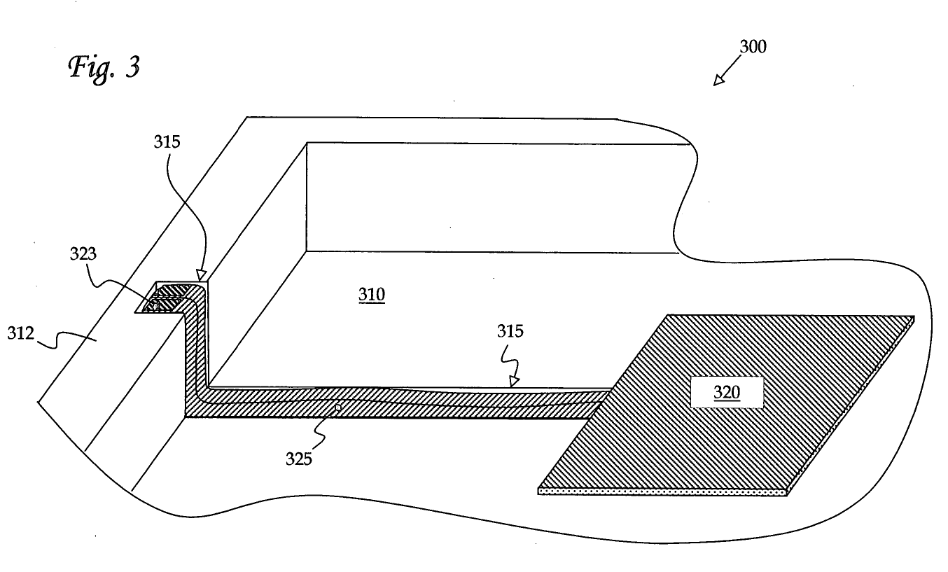

Generally, as shown in FIGS. 1 and 3, embodiments of an electrically conductive pathway 125, 325 routed along a cooling device 110, 310 may be routed along a surface of the cooling device proximate a substrate 101. This may be generally described as a ‘bottom’ or ‘inner’ surface of a cooling device 110, however, no such limitation in orientation should be imparted to this description. In the exemplary embodiment of an IHS 110 as shown in FIG. 1, the electrically conductive pathway 125 may be routed along a surface of the IHS proximate the cavity 150 of the IHS 110.

Referring to FIGS. 1 and 3, an electrically conductive pathway 125, 325 retained in close proximity to a cooling device 110, 310 may traverse from a location where it is coupled with a TFTEC 120, 320 to a location where it may be coupled with an electrically conductive feature 103, as in an exemplary embodiment, on a substrate 101. As discussed supra, an extending structure 112, 312 may be present at or near the perimeter of a cooling device 110, 310, such as a lip or rim, which extends from the main body portion 111 of a cooling device 110, 310 to a position proximate to or in contact with a substrate 101. An electrically conductive pathway 125, 325 traversing a cooling device 110, 310 may, upon reaching such an extending structure 112, 312, change angle of traversal and traverse along the extending structure from a position proximate to the main body portion 111 of the cooling device 110, 310 to a position proximate to the substrate 101 and distal from the main body portion 111 of the cooling device 110, 310. In other embodiments, a cooling device 110, 310 may not have a lip 112, 312 provided near the outer perimeter, however, another form of extending structure may be provided. An extending structure may be located near the outer perimeter of the cooling device 110, 310, or it may be provided at a location substantially within the outer perimeter of the cooling device 110, 310 where the extending structure may extend to a position proximate to an electrically conductive feature 103.

Once an end of an electrically conductive pathway 125 is presented proximate to a substrate 101, it may be presented proximate to an electrically conductive feature 103 according to any of several embodiments. In one embodiment, the end of an electrically conductive pathway 125 may continue to extend in the same orientation as that portion in contact with the extending structure 112 until the electrically conductive pathway is sufficiently proximate to the electrically conductive feature 103 to allow secure electrical coupling to be achieved, for example, at a location substantially within the outer perimeter of the cooling device 110. In other embodiments, also substantially depicted in FIGS. 1 and 3, the end of an electrically conductive pathway 125, 325 proximate a substrate 101 may change angle of traversal at or near the portion of the extending structure 112, 312 distal from the main body portion 111 of the cooling device 110, 310, and traverse to a position directly interposed between the extending structure 112, 312 and the substrate 101 so that a portion 323 of the electrically conductive pathway formed for electrical coupling with an electrically conductive feature 103 may be partially or completely presented between the extending structure 112, 312 and a substrate 101. In such embodiments, electrical coupling of an electrically conductive pathway 125, 325 to an electrically conductive feature 103 may take place entirely or substantially within the outer perimeter of the cooling device 110, 310. In still other embodiments, the end of an electrically conductive pathway 125, 325 proximate a substrate 101 may traverse as in the previously described embodiments, but may continue to a position corresponding to the outer perimeter of the cooling device 110, 310, where electrical coupling to an electrically conductive feature 103 may take place substantially or completely beyond the outer perimeter of the cooling device 110, 310.

The end of an electrically conductive pathway 125 distal from the TFTEC 120, 320 may be formed to be capable of physically coupling, as well as electrically coupling with an electrically conductive feature 103. For the purposes of clarity and simplicity throughout this description, the terms ‘formed as’, ‘formed with’, and ‘provided with’ may be used interchangeably when describing embodiments wherein, for example, the end of an electrically conductive pathway may be made capable of electrically or physically coupling with an electrically conductive feature. In an embodiment substantially depicted in FIG. 3, a pad 323 or a plurality of pads suitable for adhering to a conductive feature 103 may be provided at the end of an electrically conductive pathway 325. FIG. 3 depicts an embodiment of an electrically conductive pathway 325, the end of the pathway being formed as, or having been provided with at least one substantially flat structure (e.g., a pad or terminal) 323. In embodiments of the invention, the end of an electrically conductive pathway 125, 325 proximate to a substrate 101 may be formed as a spring device so that electrical coupling with an electrically conductive feature 103 may be maintained by applying and maintaining a load upon the cooling device in the direction of a substrate surface proximate to the cooling device, thereby compressing and maintaining compressed an electrically conductive spring device substantially in contact with the electrically conductive feature. In still other embodiments, an end of an electrically conductive pathway 125, 325 capable of electrically or physically coupling with an electrically conductive feature 103 may include at least one bare wire, at least one pin, a unit of solder or conductive adhesive applied to the end of the electrically conductive pathway, a receptacle for receiving a structure projecting from the surface of a substrate, or any combination of the embodiments described here.

An electrically conductive pathway 125, 325 may be electrically coupled with an electrically conductive feature 103 according to numerous embodiments of the invention, including adhering the pathway to the feature with a solder material, an electrically conductive epoxy, an electrically conductive polymer material, or other electrically conductive material. In embodiments, a solder material may be a metallic paste, a bulk metallic glass (BMG) solder material, a lead-free solder material, or a conventional solder material (e.g., tin-lead solder). An electrically conductive pathway 125, 325 may also be electrically coupled to an electrically conductive feature 103 by a reciprocal fit arrangement, wherein one of the feature or the pathway includes a projecting structure, for example a pin or a ball, and the other of the feature or the pathway includes a receptacle structure for receiving the projecting structure. In embodiments of a reciprocal fit arrangement, a projecting structure may be held electrically coupled with a receptacle structure by a friction fit, or by an adhesive material as described above.

Therefore, having described embodiments of an apparatus including a cooling device 310, a TFTEC 320, an electrically conductive pathway 325, means for routing and for retaining the electrically conductive pathway 325 in close proximity to the cooling device 310, an end of the electrically conductive pathway 325 being formed for electrically coupling to an electrically conductive feature 103, and having also described an assembly wherein embodiments of the described apparatus are thermally coupled with a heat generating device 102 and electrically coupled with an electrically conductive feature 103, embodiments of a method for providing embodiments of the described apparatus and assembly will now be described.

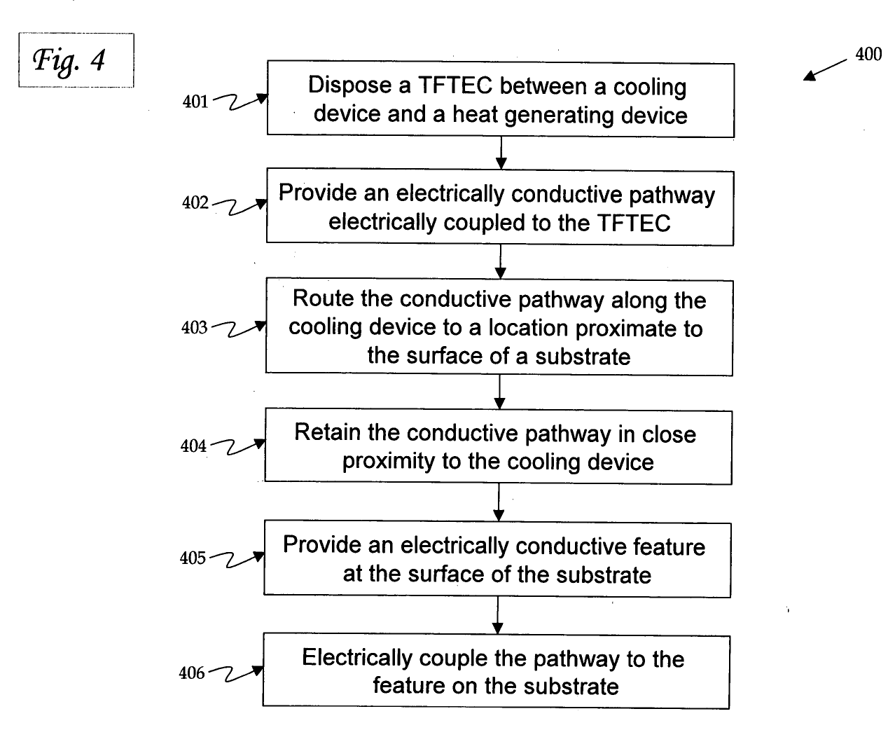

As shown in FIG. 4, a TFTEC may be disposed, at 401, between a cooling device and a heat generating device. An electrically conductive pathway that is electrically coupled to the TFTEC may be provided, at 402. At 403, an electrically conductive pathway is routed along the surface of the cooling device to a location proximate to the surface of a substrate, and the electrically conductive pathway is retained in close proximity to the cooling device, at 404. An electrically conductive feature is provided, for example, at the surface of a substrate, at 405, and the electrically conductive pathway is electrically coupled, at 406, to the electrically conductive feature.

While the embodiments of the described operations in FIG. 4, 401-406 are numbered sequentially, the order in which the embodiments of the described operations are listed pertains to only one embodiment of the invention, and no limitation in sequence is or should be interpreted as being imparted by FIG. 4. Thereby, in separate embodiments, two or more of the operations described in 401-406 may be performed concurrently, or may be performed in a sequence that varies from that shown in FIG. 4, or both.

The foregoing detailed description and accompanying drawings are only illustrative and not restrictive. They have been provided primarily for a clear and comprehensive understanding of the embodiments of the invention, and no unnecessary limitations are to be understood therefrom. Numerous additions, deletions, and modifications to the embodiments described herein, as well as alternative arrangements, may be devised by those skilled in the art without departing from the spirit of the embodiments and the scope of the appended claims.

We claim:

1. A method, comprising:
coupling an electrically conductive pathway to a thin film thermoelectric cooling (TFTEC) device, the TFTEC disposed between a second cooling device and a heat generating device;
routing the electrically conductive pathway from the TFTEC to a point proximate to the surface of a substrate,
providing an electrically conductive feature at the point proximate to the surface of the substrate; and
electrically coupling the electrically conductive pathway to the electrically conductive feature.

2. The method of claim 1, wherein the electrically conductive pathway includes at least one of a cable, a wire, and a trace.

3. The method of claim 1, wherein the heat generating device is at least one of an integrated circuit device, an integrated circuit substrate, a semiconductor device, a power regulating device, a signal processing device, and a first stage cooling device.

4. The method of claim 1, wherein at least one of the second cooling device and the first stage cooling device may be at least one of a passive cooling device and an active cooling device.

5. The method of claim 1, wherein the second cooling device includes at least one of an integrated heat spreader (IHS), a heat sink, a multi-phase cooling device, a refrigeration device, a liquid cooling device and a fan cooling device.

6. The method of claim 1, further comprising retaining a portion of the at least one electrically conductive pathway in close proximity to the second cooling device by at least one of an adhesive, a channel, a fastener, a retention structure.

7. The method of claim 1, wherein the electrically conductive feature comprises at least one of a conductive pad, a via, a via-in-pad structure, an exposed trace, an exposed power plane, an exposed ground plane, and a terminal of a component.

8. The method of claim 1, wherein electrically coupling the pathway to the feature comprises retaining the pathway in electrical contact with the feature with at least one of a solder material, an electrically conductive epoxy, an electrically conductive polymer material, and a reciprocal fit arrangement.

9. The method of claim 1, wherein routing the pathway from the TFTEC to a point proximate to the surface of a substrate comprises providing a structure extending from the second cooling device, and routing the pathway along the structure to a point proximate to the surface of a substrate.

10. The method of claim 1, wherein the electrically conductive pathway comprises at least one of a power supply pathway and a ground pathway.

11. The method of claim 1, wherein the TFTEC is thermally coupled to at least one of the heat generating device and the second cooling device.

12. The method of claim 1, wherein the electrically conductive feature is located proximate to the second cooling device.

13. The method of claim 1, wherein the substrate is an integrated circuit substrate.

14. An apparatus, comprising:
an electrically conductive pathway electrically coupled to a thin film thermoelectric cooling (TFTEC) device at one end, the other end of the at least one pathway being capable of electrically coupling to an electrically conductive feature, a portion of the electrically conductive pathway retained proximate to a second cooling device.

15. The apparatus of claim 14, wherein the electrically conductive pathway includes at least one of a cable, a wire, and a trace.

16. The apparatus of claim 14, wherein the TFTEC device is further disposed between the second cooling device and a heat generating device.

17. The apparatus of claim 16, wherein the heat generating device is an integrated circuit device.

18. The apparatus of claim 14, wherein the second cooling device includes at least one of an integrated heat spreader (IHS), a heat sink, a multi-phase cooling device, a refrigeration device, a liquid cooling device and a fan driven cooling device.

19. The apparatus of claim 14, wherein the at least one electrically conductive feature comprises at least one of a conductive pad, a via, a via-in-pad structure, an exposed trace, an exposed power plane, an exposed ground plane, and a terminal of a component.

20. The apparatus of claim 14, wherein the at least one electrically conductive pathway comprises at least one of a power supply pathway and a ground pathway.

21. The apparatus of claim 14, wherein the end of the at least one electrically conductive pathway capable of being electrically coupled to at least one electrically conductive feature comprises at least one of a bare wire, a pin, a pad, a substantially flat structure, a unit of solder, a receptacle, and a unit of conductive adhesive.

22. The apparatus of claim 14, wherein the end of the at least one electrically conductive pathway being capable of electrically coupling to at least one electrically conductive feature is located on a structure extending from a main body portion of a cooling device to a position proximate to the at least one electrically conductive feature.

23. The apparatus of claim 14, wherein at least one channel is formed into the second cooling device.

24. The apparatus of claim 14, wherein a portion of the at least one electrically conductive pathway is retained proximate to a second cooling device by at least one of an adhesive, a channel, a fastener, and a retention structure.

25. An assembly, comprising:
a substrate;
a heat generating device disposed adjacent to the substrate;
a cooling device disposed adjacent to the heat generating device;
a thin film thermoelectric cooling (TFTEC) device disposed between the heat generating device and the cooling device;
at least one electrically conductive feature on the substrate; and
at least one electrically conductive pathway electrically coupled at one end to the TFTEC device and at the other end to the at least one electrically conductive feature on the substrate.

26. The assembly of claim 25, wherein a portion of the at least one electrically conductive pathway is retained proximate to the cooling device.

27. The assembly of claim 25, wherein the substrate is an integrated circuit substrate.

28. The assembly of claim 25, wherein the heat generating device is at least one of an integrated circuit device, an integrated circuit substrate, a semiconductor device, a power regulating device, a signal processing device, and a first stage cooling device.

29. The assembly of claim 25, wherein the cooling device comprises at least one of an active cooling device and a passive cooling device.

30. The assembly of claim 25, wherein the at least one electrically conductive pathway includes at least one of a cable, a wire, and a trace.

31. The assembly of claim 25, wherein the at least one electrically conductive feature on the surface of a substrate comprises at least one of a conductive pad, a via, a via-in-pad structure, an exposed trace, an exposed power plane, an exposed ground plane, and a terminal of a component.

32. The assembly of claim 25, wherein the at least one electrically conductive pathway is at least one of a power supply pathway and a ground pathway.

33. The assembly of claim 25, wherein the at least one electrically conductive pathway is electrically coupled to the at least one electrically conductive feature on the substrate with at least one of a solder material, an electrically conductive epoxy, an electrically conductive polymer material, and a reciprocal fit arrangement.
